(19) United States
(12) Patent Application Publication
(10) Pub. No.: US 2024/0297205 A1
(43) Pub. Date: Sep. 5, 2024

(54) MICRO LIGHT-EMITTING DIODE (LED) STRUCTURE

(71) Applicant: JADE BIRD DISPLAY (SHANGHAI) LIMITED, SHANGHAI (CN)

(72) Inventors: Yuankun ZHU, Shanghai (CN); Shuang ZHAO, Shanghai (CN); Deshuai LIU, Shanghai (CN)

(21) Appl. No.: 18/594,037

(22) Filed: Mar. 4, 2024

(30) Foreign Application Priority Data
Mar. 2, 2023 (WO) PCT/CN2023/079319

(51) Int. Cl. H01L 27/15

(52) U.S. Cl. CPC H01L 27/156

(57) ABSTRACT

An exemplary micro light-emitting diode (LED) structure includes an array of micro LEDs. Each micro LED in the array includes: a bottom epitaxial layer of a first conductive type; a light-emitting layer, formed on the bottom epitaxial layer; a top epitaxial layer of a second conductive type, formed on the light-emitting layer; and a top contact layer, formed on the top epitaxial layer and having a continuous closed shape.

### CROSS-REFERENCE TO RELATED APPLICATIONS

The present disclosure claims priority to and the benefits of PCT Application No. PCT/CN2023/079319, filed on Mar. 2, 2023, which is incorporated herein by reference in its entirety.

### TECHNICAL FIELD

The present disclosure generally relates to the technical field of micro light-emitting diodes (micro LEDs), and more particularly, to a micro LED structure that constrains the electric current path.

### BACKGROUND

The micro LED showed higher output performance than conventional LEDs due to better strain relaxation, improved light-extraction efficiency, and uniform current spreading. The micro LEDs also exhibited improved thermal effects, higher current density, faster response rate, larger working temperature range, higher resolution, wider color gamut, higher contrast, and lower power consumption, as compared with conventional LEDs.

A micro LED structure includes an array of pixels. It typically includes micro lens, transparent conductive film layer (e.g., indium tin oxide or “ITO”), top contact layer, epitaxial wafer, insulating layer, reflective layer, bottom contact layer, dielectric layer, and integrated-chip (IC) chip layer, of which the epitaxial wafer further includes top epitaxial layer, light-emitting layer, and bottom epitaxial layer layers. Among them, the top contact layer is used to expand the current between adjacent pixels, and the bottom contact layer is bonded with the IC back plane.

However, in a conventional micro LED structure, the structure of the top contact layer results in a poor electric current path within the array of pixels. Therefore, it is desirable to improve the structure of the top contact layer.

### SUMMARY

In view of the technical problem associated with the electric current path in existing micro LED structures, the present disclosure proposes a specially shaped electrode metal layer, which can constrain an electric current path and improve a micro LED structures' performance.

According to some disclosed embodiments, an exemplary structure for a micro LED array is provided. The structure comprises an array of micro LEDs. Each micro LED in the array comprises: a bottom epitaxial layer of a first conductive type; a light-emitting layer, formed on the bottom epitaxial layer; a top epitaxial layer of a second conductive type, formed on the light-emitting layer; and a top contact layer, formed on the top epitaxial layer and having a continuous closed shape.

### BRIEF DESCRIPTION OF THE DRAWINGS

The accompanying drawings, which are incorporated in and constitute a part of this specification, illustrate embodiments consistent with the present disclosure and, together with the description, serve to explain the principles of the present disclosure.

FIG. 1 is a cross-sectional view schematically showing an exemplary micro LED structure with an annular electrode, according to some embodiments of the present disclosure.

FIG. 2 is a plan view of the micro LED structure in FIG. 1 (without showing the micro lens and ITO layer in FIG. 1), according to some embodiments of the present disclosure.

FIG. 3 is a cross-sectional view schematically showing an exemplary micro LED structure with a circular electrode, according to some embodiments of the present disclosure.

FIG. 4 is a plan view of the micro LED structure in FIG. 3 (without showing the micro lens and ITO layer in FIG. 3), according to some embodiments of the present disclosure.

FIG. 5 is a cross-sectional view schematically showing an exemplary micro LED structure with an annular-square electrode, according to some embodiments of the present disclosure.

FIG. 6 is a plan view of the micro LED structure in FIG. 5 (without showing the micro lens and ITO layer in FIG. 5), according to some embodiments of the present disclosure.

FIG. 7 is a cross-sectional view schematically showing an electric current path in an exemplary micro LED structure with a circular electrode, according to some embodiments of the present disclosure.

FIG. 8 is a cross-sectional view schematically showing an electric current path in an exemplary micro LED structure with an annular electrode, according to some embodiments of the present disclosure.

FIG. 9 is a cross-sectional view schematically showing an electric current path in an exemplary micro LED structure with an annular-square electrode, according to some embodiments of the present disclosure.

### DETAILED DESCRIPTION

Reference will now be made in detail to exemplary embodiments, examples of which are illustrated in the accompanying drawings. The following description refers to the accompanying drawings in which the same numbers in different drawings represent the same or similar elements unless otherwise represented. The implementations set forth in the following description of exemplary embodiments do not represent all implementations consistent with the invention. Instead, they are merely examples of apparatuses and methods consistent with aspects related to the invention as recited in the appended claims. Particular aspects of the present disclosure are described in greater detail below. The terms and definitions provided herein control, if in conflict with terms and/or definitions incorporated by reference.

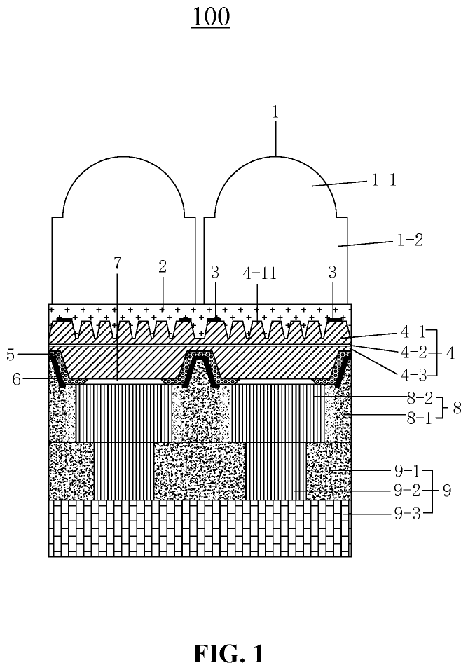

FIG. 1 a cross-sectional view schematically showing an exemplary micro LED structure 100 with a constrained electric current path, according to some embodiments of the present disclosure. More particularly, micro LED structure 100 includes an array of pixels implemented in a micro LED display device. FIG. 1 shows a portion of the array of pixels. As shown in FIG. 1, along a direction from a front side (i.e., a lens side) of micro LED structure 100 to a back side (i.e., a circuit side) of micro LED structure 100, it includes an array of micro lenses 1, a top conductive layer 2, a top contact layer 3, an epitaxial wafer 4, an insulating layer 5, a reflective layer 6, a bottom contact layer 7, a bottom conductive structure 8, and an integrated circuit (IC) backplane 9. In some embodiments, top conductive layer 2 is transparent and includes indium tin oxide (ITO), and thus also called “ITO layer 2.” However, it is contemplated that the material of top conductive layer 2 is not limited to ITO.

Additionally, the top contact layer 3 is formed on the top epitaxial layer and continuously formed in a closed shape. In some embodiments, the closed shape comprises: a circular shape, an annular shape, or an annular-square shape with an annular inner portion and a square peripheral portion. Furthermore, the top contact layer 3 is continuously formed on the top epitaxial layer in the micro LED array. In some embodiments, the top contact layer 3 is formed at the edge of each micro LED structure and around the center axis of each micro LED structure.

Furthermore, the top epitaxial layer 4-1 comprises a first trench between the adjacent micro LEDs; and the bottom epitaxial layer 4-3 comprises a second trench between the adjacent micro LEDs. In the embodiment, the top contact layer 3 is formed on the surface of the top epitaxial layer 4-1 at the edge of the first trench. The first trench is formed at the position corresponding to the second trench.

More specifically, in the embodiment shown in FIG. 1, bottom conductive structure 8 is disposed on IC backplane 9. Specifically, the bottom conductive structure 8 includes a first dielectric layer 8-1 and a first array of contact holes 8-2 formed in first dielectric layer 8-1. Each contact hole 8-2 may have a cylindrical shape. A first metal is filled in the first array of cylindrical contact holes 8-2. An insulating layer 5 is filled into the second trench; furthermore, the insulating layer 5 is formed on the sidewall and the bottom of the second trench. A reflective layer 6 is formed on the surface of the insulating layer but not connected to the contact hole 8-2.

Moreover, in each micro LED: the bottom contact 7 is formed on the bottom surface of the bottom epitaxial layer 4-3; epitaxial layer 4 is formed on the bottom contact layer 7; the ITO layer 2 is formed on epitaxial layer 4; the micro lens 1 is formed on the ITO layer 2 and has a lens shape; and top contact layer 3 is formed on the top epitaxial layer 4-3 between the epitaxial layer 4 and the ITO layer 2. The top contact layer 3 includes conductive material, such as pure metal or metal alloy. The bottom contact 7 includes conductive material, such as pure metal or metal alloy. Each of the micro lenses 1 includes a top hemisphere lens 1-1 and a lens base 1-2 below top hemisphere lens 1-1. A width of bottom spacer 1-2 is greater than a diameter of top hemisphere lens 1-1. A height of lens base 1-2 is dependent on the diameter of top hemisphere lens 1-1, e.g., the height of lens base 1-2 increases as the diameter of top hemisphere lens 1-1 increases. Gaps are formed between adjacent micro lenses 1.

In some embodiments, ITO layer 2 comprises N-type oxide semiconductor-indium tin oxide (ITO).

As also shown in FIG. 1, in some embodiments, epitaxial wafer 4 includes a top epitaxial layer 4-1, a light-emitting layer 4-2, and a bottom epitaxial layer 4-3. Top epitaxial layer 4-1 is a semiconductor epitaxial layer with a first conductive type, and bottom epitaxial layer 4-3 is a semiconductor epitaxial layer with a second conductive type. As an example, the first conductive type is N-type, and the second conductive type is P-type. As another example, the first conductive type is P-type, and the second conductive type is N-type. The structures of these layers are described below in detail.

In particular, in some embodiments, top epitaxial layer 4-1 may further include (not shown in FIG. 1): an n-GaAs (i.e., N-type GaAs) layer having a thickness between 10 nm-1000 nm, inclusive; and/or a Si-doped n-AlInP (i.e., N-type AlInP) layer having a thickness between 10 nm-10 micrometers, inclusive. The above exemplary numerical values are for illustrative purposes only and are not intended to be used to limit the present disclosure.

In some embodiments, to improve the light-extraction efficiency within micro LED structure 101, top epitaxial layer 4-1 is configured to form a plurality of photonic crystals 4-11 at an interface between top epitaxial layer 4-1 and ITO layer 2. Consistent with the disclosed embodiments, the plurality of photonic crystals 4-11 may be configured to have shapes and sizes that are suitable for improving the light-extraction efficiency. For example, as shown in FIG. 1, each of the plurality of photonic crystals 4-11 may have a conical shape. As another example, each of the plurality of photonic crystals 4-11 has a height of approximately 300 nm and a diameter of approximately 266 nm, and adjacent photonic crystals 4-11 may be spaced by a distance of approximately 50 nm. Nonetheless, the disclosed embodiments are not limited to any particular shape or dimensions of the photonic crystals. For example, each of the plurality of photonic crystals 4-11 may have a cylindrical shape (not shown in FIG. 1).

In some embodiments, light-emitting layer 4-2 includes one or more layers of the InGaP/AlGaInP quantum well, each layer of the InGaP/AlGaInP quantum well including an InGaP sub-layer and an AlGaInP sub-layer. For example, light-emitting layer 4-2 may include 1-20 layers of the InGaP/AlGaInP quantum well. As another example, in each layer of the InGaP/AlGaInP quantum well, the thickness of the InGaP sub-layer is approximately 3.5 nm, and the thickness of the AlGaInP sub-layer is approximately 6.5 nm. The above exemplary numerical values are for illustrative purposes only and are not intended to be used to limit the present disclosure.

In some embodiments, to improve the quantum wells' well plug effect (WPE) performance, light-emitting layer 4-2 is configured to form an integrated connected structure over the array of pixels, i.e., light-emitting layer 4-2 is interconnected between adjacent pixels. “WPE” is defined as the ratio of optical output power over consumed electrical input power as measured at a wall plug. By forming light-emitting layer 4-2 as an integrated connected structure over the array of pixels, high WPE can be achieved in micro LED structure 101, thereby ensuring high performance of the LED display device.

In some embodiments, bottom epitaxial layer 4-3 includes a Mg-doped p-AlInP layer having a thickness between 50 nm-300 nm, inclusive. These numerical values are for exemplary purposes only and are not intended to be used to limit the present disclosure.

As shown in FIG. 1, in some embodiments, bottom epitaxial layer 4-3 forms an array of inverted trapezoidal shapes or an array of bowl shapes at an interface between bottom epitaxial layer 4-3 and bottom conductive structure 8.

FIG. 1 also shows an exemplary structure to achieve bonding between bottom conductive structure 8 and IC backplane 9. IC backplane 9 includes a second dielectric layer 9-1, a second array of contact holes 9-2 formed in second dielectric layer 9-1, and a chip circuit board 9-3 formed below second dielectric layer 9-1 and second array of contact holes 9-2. Each contact hole 9-2 may have a cylindrical shape. A second metal is filled in the second array of cylindrical contact holes 9-2. First array of contact holes 8-2 forms a one-to-one relationship with the second array of contact holes 9-2. Each contact hole 8-2 may have a width (or a diameter if contact hole 8-2 has a cylindrical shape) greater that the width (or diameter) of the corresponding contact hole 9-2. The first metal in the first array of cylindrical contact holes 8-2 is respectively bonded to the second metal in the second array of cylindrical contact holes 9-2. In sum, the array of bottom contact pad 7 respectively corresponds to an array of pixels and is electrically connected to the first metal in first array of contact holes 8-2 respectively, which is further electrically connected to the second metal in second array of contact holes 9-2 respectively.

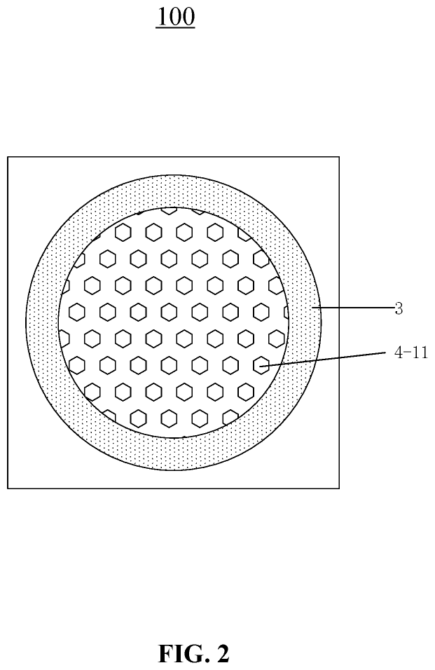

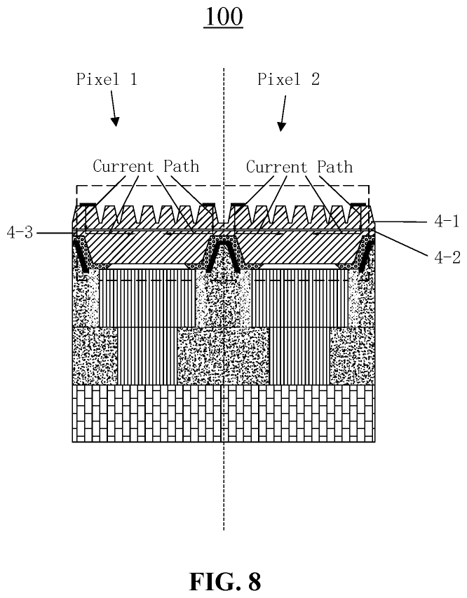

FIG. 2 is a plan view of micro LED structure 100, according to some embodiments of the present disclosure. To help illustrate the structure of top contact layer 3, micro lens 1 and ITO layer 2 are not shown in FIG. 2. Moreover, FIG. 2 only shows one pixel in vertical view. It is contemplated that other pixels of micro LED structure 100 have the same plan-view structure. As collectively shown by FIGS. 1 and 2, in each pixel of micro LED structure 100, top contact layer 3 is shaped as a ring (i.e., an annulus) that surrounds a plurality of photonic crystals 4-11. FIG. 8 is a cross-sectional view schematically showing an electric current path in micro LED structure 100, according to some embodiments of the present disclosure. The arrows in FIG. 8 show an electric current path in each pixel. As shown in FIG. 8, in each pixel, ring-shaped top contact layer constrains the electric current path to the respective pixel, thereby reducing the electric current crosstalk between adjacent pixels.

Consistent with the disclosed embodiments, top contact layer 3 can have any shape suitable for constraining electric current path. Besides ring-shaped top contact layer 3 shown in FIGS. 1, 2, and 8, two alternative exemplary shapes of top contact layer 3 are described below.

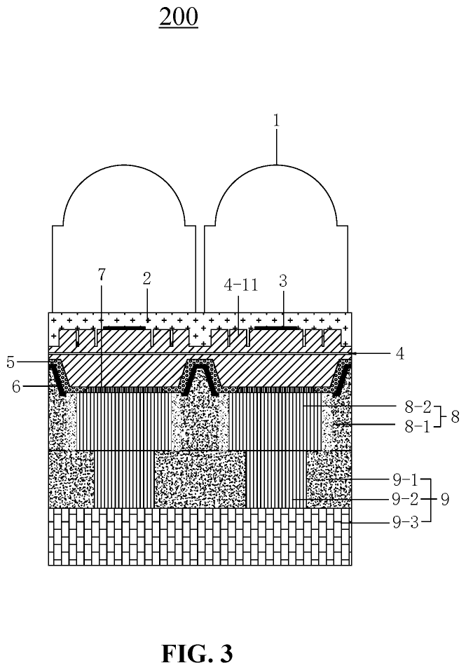

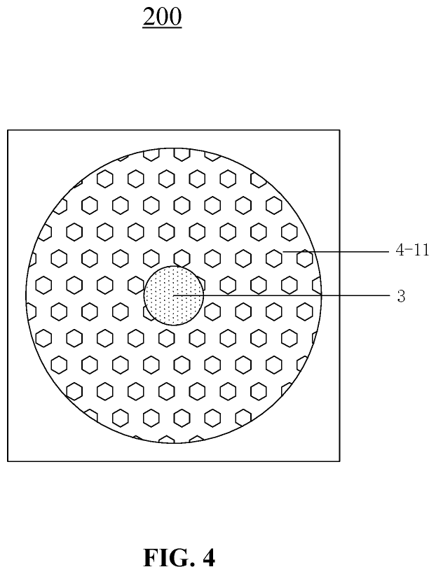

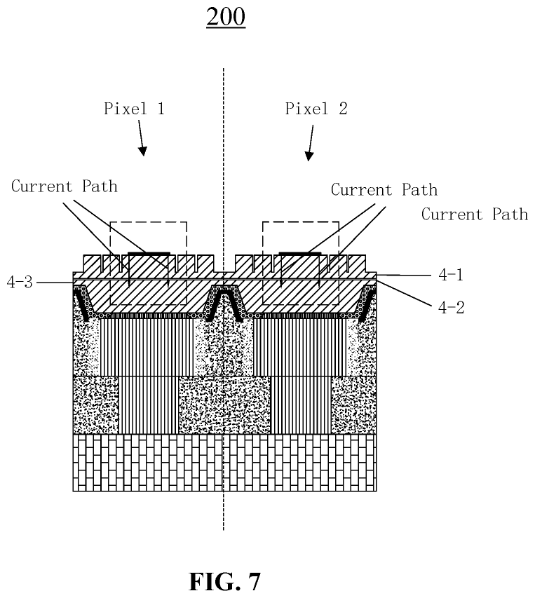

According to some embodiments, FIG. 3 schematically shows a cross-sectional view of a micro LED structure 200, and FIG. 4 schematically shows a plan view of micro LED structure 200. Micro LED structure 200 includes an array of pixels implemented in a micro LED display device, and FIG. 3 shows a portion of the array of pixels. FIG. 4 only shows one pixel of micro LED structure 200. Micro lens 1 and ITO layer 2 are excluded from FIG. 4 to help illustrate the plan-view structure of top contact layer 3 in each pixel. As collectively shown by FIGS. 3 and 4, micro LED structure 200 is generally similar to micro LED structure 100 (FIGS. 1, 2, and 8), with the difference lying in the shape of top contact layer 3 in each pixel. Specially, each pixel of micro LED structure 200 has a top contact layer 3 shaped as a circular plate in vertical view. Also, in vertical view, top contact layer 3 is generally located at the center of the respective pixel. FIG. 7 is a cross-sectional view schematically showing an electric current path in micro LED structure 200, according to some embodiments of the present disclosure. The arrows in FIG. 7 show an electric current path in each pixel. As shown in FIG. 7, in each pixel, circular top contact layer constrains the electric current path to the respective pixel, thereby reducing the electric current crosstalk between adjacent pixels.

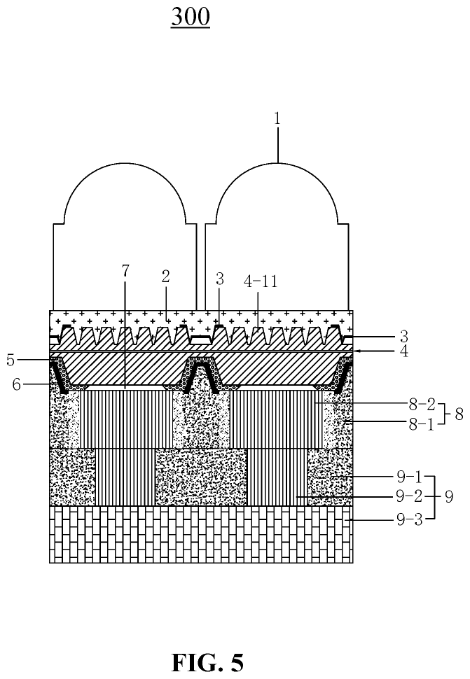

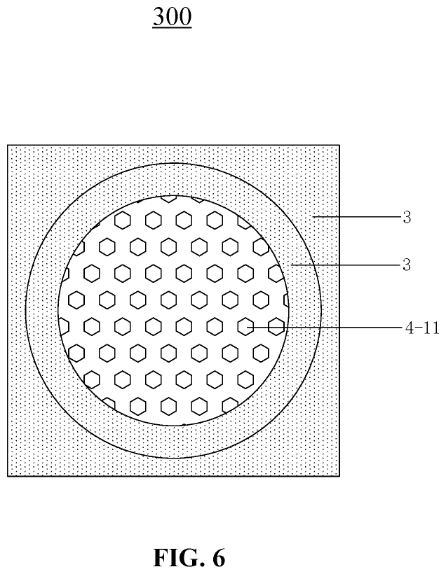

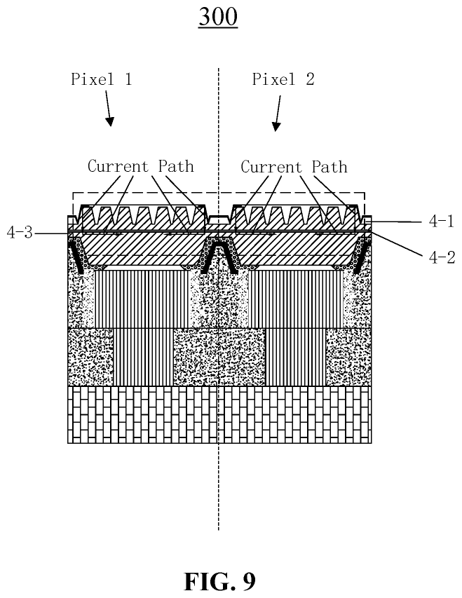

According to some embodiments, FIG. 5 schematically shows a cross-sectional view of a micro LED structure 300, and FIG. 6 schematically shows a plan view of micro LED structure 300. Micro LED structure 300 includes an array of pixels implemented in a micro LED display device, and FIG. 5 shows a portion of the array of pixels. FIG. 6 only shows one pixel of micro LED structure 300. Micro lens 1 and ITO layer 2 are excluded from FIG. 6 to help illustrate the plan-view structure of top contact layer 3 in each pixel. As collectively shown by FIGS. 5 and 6, micro LED structure 300 is generally similar to micro LED structure 100 (FIGS. 1, 2, and 8), with the difference lying in the shape of top contact layer 3 in each pixel. Specially, in vertical view (FIG. 6), each pixel of micro LED structure 300 has a top contact layer 3 shaped as a square with a round open center. And as shown in the cross-sectional view of FIG. 5, top contact layer 3 in each pixel has a peripheral portion formed in grooves between adjacent pixels, and has an inner portion formed on photonic crystals 4-11. In vertical view (FIG. 6), the inner portion has a ring shape. Therefore, the shape of top contact layer 3 in micro LED structure 300 is also referred to as an “annular-square” shape in three-dimensional view. The annular-square shape includes an annular inner portion and a square peripheral portion, the annular inner portion and square peripheral portion having different elevations in cross-sectional view (FIG. 5). In vertical view (FIG. 6), the annular-square shape is shown as a square with a round hollow center. FIG. 9 is a cross-sectional view schematically showing an electric current path in micro LED structure 300, according to some embodiments of the present disclosure. The arrows in FIG. 9 show an electric current path in each pixel. As shown in FIG. 9, in each pixel, circular top contact layer constrains the electric current path to the respective pixel, thereby reducing the electric current crosstalk between adjacent pixels.

In sum, as described above, the disclosed micro LED structures (i.e., micro LED structures 100-300) each have a constrained electric current path.

In sum, the present disclosure provides micro LED structures with a constrained electric current path.

According to some disclosed embodiments, an exemplary micro LED structure includes: an integrated circuit (IC) back plane; a bottom conductive structure disposed on the IC back plane; a reflective layer disposed on the bottom conductive structure, the reflective layer defining an array of pixels; and an insulating layer disposed on the reflective layer. Each of the pixels includes: a bottom contact layer disposed on the bottom conductive structure; an epitaxial wafer disposed on the bottom contact layer; an indium tin oxide (ITO) layer disposed on the epitaxial wafer; a micro lens disposed on the ITO layer; and a top contact layer disposed between the epitaxial wafer and the ITO layer. The epitaxial wafer of each of the pixels includes a top epitaxial layer, a light-emitting layer, and a bottom epitaxial layer. The top contact layer of each of the pixels has: a circular shape, an annular shape, or an annular-square shape with an annular inner portion and a square peripheral portion.

The disclosed circular, annular, and annular-square top contact layer constrains electric current path in the micro LED structures.

Moreover, in the disclosed micro LED structures, the light-emitting layer is interconnected between adjacent pixels. Such an interconnected quantum well structure enhances the well plug effect (WPE) performance of micro LED chips.

According to some disclosed embodiments, the top epitaxial layer of each of the pixels forms a plurality of photonic crystals at an interface between the top epitaxial layer and the ITO layer. The photonic crystals are used to improve the micro LED structures' light-extraction efficiency. The shape of the photonic crystals can be designed according to experimental data regarding the light-extraction efficiency. For example, the photonic crystals may be designed to be cylindrical or conical. Such shapes generally can achieve satisfactory light-extraction efficiency.

Consistent with the disclosed embodiments, the photonic crystals can have any suitable height, diameter, and/or spacing distance. For example, the photonic crystals may have a height of 300 nm, and/or a diameter of 266 nm. And adjacent photonic crystals may be separated by a spacing distance of 50 nm.

The present invention is further set up as follows: the top epitaxial layer between adjacent pixels is set as an integrated connected structure.

According to some disclosed embodiments, the top epitaxial layer is interconnected between adjacent pixels, so as to form an interconnected structure across the array of pixels. Such an interconnected top epitaxial layer facilitates electric current expansion. For example, the top epitaxial layer forms a continuous bottom surface across the array of pixels. In some embodiments, the bottom epitaxial layer is interconnected across the array of pixels. For example, the bottom epitaxial layer forms a continuous top surface across the array of pixels.

According to some disclosed embodiments, the bottom epitaxial layer forms an array of inverted trapezoidal shapes or an array of bowl shapes at an interface between the bottom epitaxial layer and the bottom conductive structure. As a result, the bottom of the inverted trapezoidal structure or bowl structures can reflect the light emitted from the quantum well to its periphery, so as to further gather the light and improve light utilization.

According to some disclosed embodiments, the ITO layer is N-type oxide semiconductor-indium tin oxide (ITO). The ITO layer improves electric current expansion between adjacent pixels.

According to some disclosed embodiments, the bottom conductive structure includes first dielectric material and first metal. A first array of cylindrical contact holes is formed in the first dielectric material and the first metal is filled in the first array of cylindrical contact holes. Moreover, the IC back plane includes a second dielectric layer, second metal, and a chip circuit board. The second dielectric layer includes a second array of cylindrical contact holes, and the second metal is filled in the second array of cylindrical contact holes. The first metal in the first array of cylindrical contact holes is respectively bonded to the second metal in the second array of cylindrical contact holes. As a result, the bottom conductive structure is bonded to the IC backplane.

In sum, the disclosed micro LED structures use a top contact layer with specially designed shapes to constrain electric current path. For example, the top contact layer in each pixel may have a circular shape, an annular shape, or an annular-square shape. Moreover, the quantum well between adjacent pixels is formed as an integrated connected structure across the array of pixels. Such integrated connected quantum well enhances the performance of micro LED chips. Additionally, by etching the epitaxial wafer to form the photonic crystals, the micro LED structures' light-extraction efficiency is improved. The shape of the photonic crystals can be designed according to experimental data regarding the light-extraction efficiency. For example, the photonic crystals may be designed to be cylindrical or conical. Such shapes generally can achieve satisfactory light-extraction efficiency.

As used herein, unless specifically stated otherwise, the term “or” encompasses all possible combinations, except where infeasible. For example, if it is stated that a database may include A or B, then, unless specifically stated otherwise or infeasible, the database may include A or B, or A and B. As a second example, if it is stated that a database may include A, B, or C, then, unless specifically stated otherwise or infeasible, the database may include A or B, or C, or A and B, or A and C, or B and C, or A, B, and C.

It will be appreciated that the embodiments of the present disclosure are not limited to the exact construction that has been described above and illustrated in the accompanying drawings, and that various modifications and changes may be made without departing from the scope thereof. While the present disclosure has been described in connection with various embodiments, other embodiments of the invention will be apparent to those skilled in the art from consideration of the specification and practice of the invention disclosed herein. It is intended that the specification and examples be considered as exemplary only, with a true scope and spirit of the invention being indicated by the following claims.

The descriptions above are intended to be illustrative, not limiting. Thus, it will be apparent to one skilled in the art that modifications may be made as described without departing from the scope of the claims set out below.

What is claimed is:

1. A microlight-emitting diode (LED) structure, comprising:
an array of micro LEDs, wherein each micro LED in the array comprises:
a bottom epitaxial layer of a first conductive type;
a light-emitting layer, formed on the bottom epitaxial layer;
a top epitaxial layer of a second conductive type, formed on the light-emitting layer; and
a top contact layer, formed on the top epitaxial layer and having a continuous closed shape.

2. The micro LED structure according to claim 1, wherein the continuous closed shape comprises: a circular shape, an annular shape, or an annular-square shape with an annular inner portion and a square peripheral portion.

3. The micro LED structure according to claim 1, wherein the top contact layer is continuously formed on the top epitaxial layer in the array of micro LEDs.

4. The micro LED structure according to claim 1, wherein the top contact layer is formed at an edge of the respective micro LED and around a center axis of the respective micro LED.

5. The micro LED structure according to claim 1, wherein the top contact layer comprises a conductive material.

6. The micro LED structure according to claim 5, wherein the conductive material of the top contact layer is metal.

7. The micro LED structure according to claim 1, wherein each micro LED in the array further comprises a top conductive layer formed on the top epitaxial layer and the top contact layer.

8. The micro LED structure according to claim 7, wherein the top conductive layer is transparent and comprises indium tin oxide (ITO).

9. The micro LED structure according to claim 1, wherein the top epitaxial layer comprises a first trench between adjacent micro LEDs.

10. The micro LED structure according to claim 9, wherein the top contact layer is formed at an edge of the first trench.

11. The micro LED structure according to claim 9, wherein the bottom epitaxial layer comprises a second trench formed at a position corresponding to the first trench.

12. The micro LED structure according to claim 1, wherein each micro LED in the array further comprises a micro lens formed above the top epitaxial layer.

13. The micro LED structure according to claim 12, wherein a gap is formed between the micro lens and an adjacent micro lens.

14. The micro LED structure according to claim 12, wherein the micro lens comprises a top hemisphere lens and a bottom spacer below the top hemisphere lens.

15. The micro LED structure according to claim 14, wherein a width of the bottom spacer is greater than a diameter of the top hemisphere lens.

16. The micro LED structure according to claim 14, wherein a height of the bottom spacer is determined based on a diameter of the top hemisphere lens.

17. The micro LED structure according to claim 1, wherein:
the bottom epitaxial layer comprises a second trench between adjacent micro LEDs; and
each micro LED in the array further comprises a reflective layer formed on a sidewall of the second trench.

18. The micro LED structure according to claim 17, wherein each micro LED in the array further comprises an insulating layer formed between the second trench and the reflective layer.

19. The micro LED structure according to claim 18, wherein each micro LED in the array further comprises:
a bottom contact pad formed at a bottom surface of the bottom epitaxial layer; and
a bottom conductive structure formed below the bottom contact and the bottom epitaxial layer;
wherein the bottom contact pad is surrounded by the insulating layer and electrically connected to the bottom conductive structure.

20. The micro LED structure according to claim 1, wherein each micro LED in the array further comprises:
a bottom conductive structure below the bottom epitaxial layer; and
an integrated circuit (IC) back plane formed below and electrically connected to the bottom conductive structure.

21. The micro LED structure according to claim 20, wherein:
the bottom conductive structure comprises a first dielectric layer and a first contact hole formed in the first dielectric layer; and
the IC back plane comprises a second dielectric layer and a second contact hole formed in the second dielectric layer, the second contact hole corresponding to the first contact hole.

22. The micro LED structure according to claim 21, wherein a width of the first contact hole is greater than a width of the second contact hole.

23. The micro LED structure according to claim 21, wherein a first metal is filled in the first contact hole and a second metal is filled in the second contact hole.

24. The micro LED structure according to claim 23, the first metal in the first contact hole is bonded to the second metal in the second contact hole.

25. The micro LED structure according to claim 21, wherein the IC back plane further comprises:
a chip circuit board formed below the second dielectric layer and the second contact hole.

26. The micro LED structure according to claim 1, wherein the top epitaxial layer comprises a plurality of photonic crystals.

27. The micro LED structure according to claim 26, wherein each of the plurality of photonic crystals has a cylindrical shape or a conical shape.

28. The micro LED structure according to claim 26, wherein each of the plurality of photonic crystals has a height of 300 nm and a diameter of 266 nm, and adjacent photonic crystals are spaced by a distance of 50 nm.

29. The micro LED structure according to claim 1, wherein the top epitaxial layer is interconnected between adjacent micro LEDs.

30. The micro LED structure according to claim 29, wherein the top epitaxial layer forms a continuous bottom surface across the array of micro LEDs.

31. The micro LED structure according to claim 1, wherein the light-emitting layer is interconnected between adjacent micro LEDs.

32. The micro LED structure according to claim 1, wherein the bottom epitaxial layer is interconnected between adjacent micro LEDs.

33. The micro LED structure according to claim 32, wherein the bottom epitaxial layer forms a continuous top surface across the array of micro LEDs.

34. The micro LED structure according to claim 1, wherein the bottom epitaxial layer forms an inverted trapezoidal shape or a bowl shape.

35. The micro LED structure according to claim 1, wherein:
the first conductive type is N-type and the second conductive type is P-type; or
the first conductive type is P-type and the second conductive type is N-type.
